(19) United States
(12) Patent Application Publication
(10) Pub. No.: US 2005/0128531 A1
(43) Pub. Date: Jun. 16, 2005

(54) Method and apparatus of forming an image on a reversible image display medium

(75) Inventors: Denji Nota, Ashiya-shi (JP); Takaaki Shirai, Sakai-shi (JP); Keyaki Yogome, Kyoto-shi (JP)

Correspondence Address: BRINKS HOFER GILSON & LIONE, P.O. BOX 10395, CHICAGO, IL, 60610, US

(73) Assignee: KONICA MINOLTA HOLDINGS, INC.

(21) Appl. No.: 11/002,867

(22) Filed: Dec. 2, 2004

(30) Foreign Application Priority Data
Dec. 10, 2003 (JP) 2003-411951 PAT.

(51) Int. Cl. H04N 1/04; G03F 3/10

(52) U.S. Cl. 358/474; 358/527

(57) ABSTRACT

An image forming method and an image forming apparatus of forming an image on a reversible image display medium of dry developing particle moving type including substrates made of a nonconductive material. The medium is transported for forming an image on the medium while keeping the medium in uniform surface-contact with an electrostatic field applying member (e.g., a photosensitive drum carrying an electrostatic latent image) for image formation by a developing bias applying conductive member (e.g., conductive belt).

### CROSS-REFERENCE TO RELATED APPLICATION

This application is based on Japanese patent application No. 2003-411951 filed in Japan on Dec. 10, 2003, the entire content of which is hereby incorporated by reference.

### BACKGROUND OF THE INVENTION

1. Field of the Invention

The present invention relates to a method and an apparatus of forming an image on a reversible image display medium, which allows reversible formation and erasing of images, and is reusable.

2. Description of the Related Art

At present, word processors, personal computers or the like display or output images by displaying by display devices or printing by printers.

The display device generally displays images at a low resolution, and therefore is not suitable for display of text documents primarily composed of characters. Also, the display device tends to cause serious eyestrain due to light-emission display when an operator operates for a long time.

Meanwhile, the printer provides easy-on-the-eyes images owing to reflective display at a high resolution, but requires long time for printing. Also, it requires electricity charges and consumables, and thus requires high running costs. Recently, there has been a tendency to reduce environmental loads, and thereof the printers have been required to reduce energy consumption and amounts of consumables such as paper. However, these demands have not been sufficiently satisfied.

In view of the above, image display mediums, which are rewritable and reusable, have been studied, and various proposals have been made.

As such image display mediums, rewritable field-driven image display mediums (i.e., rewritable image display mediums of a field driven type) have been proposed. In this image display medium a display layer having optical characteristics, which varies in response to application of an electric field, is arranged between a pair of substrates, and the electric field corresponding to an image to be displayed is applied to the display layer to display the image.

As a field-driven image display medium, Japanese Laid-Open Patent Publication No. 2001-290179 has disclosed a reversible image display medium, which is rewritable and is of a dry developing particle moving type. In this image display medium, dry developer is contained between paired substrates. The dry developer includes at least two kinds of developing particles having frictional charging properties and being different in charging polarity and optical reflectance density from each other. By applying an electric field corresponding to an intended image, the two kinds of developing particles are moved oppositely to each other, and thereby the medium displays the image.

Also, Japanese Laid-Open Patent Publication No. 2001-290179 has disclosed the reversible image display medium, in which magnetic particles are used as one kind of the frictionally chargeable developing particles, which have the charging polarity and the optical reflection density different from those of the other kind of particles. In the image display operation, a magnetic field (particularly, oscillating magnetic field) is applied in addition to the electric field so that a last image can be erased before forming a new image, and developing particles can be moved easily for image formation.

Japanese Laid-Open Patent Publication No. 2001-290179 has further disclosed a rewritable image display medium of an electrophoretic type having a display layer, which is formed of particles having an electrophoretic capability and a display liquid. The display liquid is formed of a dispersion medium containing the particles in a dispersed fashion.

U.S. Pat. No. 6,222,513 B1 has disclosed a rewritable image display medium of a twist ball type, which has a display layer made of a holding medium, in which capsules rotatably accommodating particles are dispersed. Each particle has a surface, which is divided into halves of different colors. By applying an electric field to the particles, the particles rotate to display an image.

Among the above structures, the reversible image display medium of the dry developing particle moving type disclosed in Japanese Laid-Open Patent Publication No. 2001-290179 can achieve the display with high contrast and high resolution, and can exhibit display characteristics close to those of paper mediums when displaying documents such as text documents. This reversible image display medium can achieve higher contrast in image display than the electrophoretic image display medium, and can achieve a higher resolution than the twist-ball-type image display medium.

Further, in contrast to a conventional image formation by an electrophotographic printer, the reversible image display medium of the dry developing particle moving type does not require processing of thermally melting and fixing toner onto a sheet, and thus does not require a majority of an image forming energy required in such a conventional printer.

As described above, the reversible image display medium of the dry developing particle moving type is superior to those of the other types, and this type of image display medium can form images, e.g., in the following manner.

As shown by way of example in FIG. 9, a conductive layer L made of ITO or the like is formed in advance on a rear surface of a reversible image display medium S of a dry developing particle moving type. This medium S is transported while keeping a flat form, and an electrostatic latent image corresponding to an original image or image data is formed on a rotating photosensitive drum PC. The medium S is transported and brought into contact with the photosensitive drum PC while keeping a flat state. Also, a developing bias application roller R is brought into contact with the conductive layer L on the rear surface of the medium so that the roller R presses the medium S onto the photosensitive drum PC.

According to this manner, the contact of the electrostatic latent image with the surface of the medium S and the application of the developing bias to the rear surface of the medium form an electrostatic field, which causes a Coulomb force moving the dry developing particles in the medium S to form an image. If the dry developing particles contain magnetic particles, the roller R containing a magnet roller r having N- and S-type polarities may be used, and the rollers R and r may be rotated independently of each other.

For forming good images more reliably, the medium S may be in contact with the electrostatic latent image for a long time. For ensuring such a long contact time, as shown in FIG. 10, two rollers R1 and R2 may be used to press the medium S onto the photosensitive drum PC while transporting the medium S, and one (R1) of the rollers may be used as the developing bias application roller. If the dry developing particles contain the magnetic particles, the other roller R2 may include the magnet roller r arranged within a sleeve Rs, which can rotate in contact with the medium S, and the roller r and the sleeve Rs may be rotated independently of each other.

As shown in FIG. 10, if the medium S is curved along the photosensitive drum PC when it is being transported in contact with the photosensitive drum PC, this can increase the time of contact between the medium S and the electrostatic latent image, and thus can provide good images more reliably.

According to study by the inventors, however, the above structures suffer from the following problems.

(1) Since the conductive layer L made of ITO or the like is formed on the medium S, the medium S is very expensive.

(2) Since the medium S includes the conductive layer L, which is in contact with the developing bias application roller supplied with the bias, a user may receive an electric shock depending on a structure of the image forming apparatus and a resistance of the conductive layer L, when the user touches the medium, which is being discharged. For preventing the electric shock, an additional structure is required so that the image forming apparatus becomes more expensive.

(3) Typically, the medium S has a structure, which is shown by way of example in FIG. 11. In this structure, partitions w form a plurality of cells between a pair of substrates s1 and s2 forming the medium S for preventing irregular movement of the developing particles, and these partitions w are arranged not in a grid-like form but in a parallel form for increasing a display area. Each linear cell accommodates developer DL containing developing particles. If the medium S having the above structure is pressed onto the photosensitive drum PC by the two rollers R1 and R2, the medium S may be irregularly bent as shown in FIG. 12, and/or the substrate adhered to the partitions w may be peeled off.

The cause of the above problem may be considered as follows. When the medium S is wound around the photosensitive member usually having a diameter of about 30 mm, the medium S is not bent uniformly, but is largely bent at a weak portion so that a local stress occurs to cause breakage of the partition w and peeling of the substrate. Even if the medium is transported in a direction perpendicular to the longitudinal direction of the linear cell, the linear cells cause a large resistance to bending, owing to differences in width of the partitions w and adhesion between the substrate and the partitions w.

(4) When the medium S is wound around the photosensitive drum PC, a partial space may be formed between the medium S and the photosensitive drum due to irregularity in curvature of the medium S. This space may blur the electrostatic latent image written onto the medium S, and may impede good image formation.

The above problems (3) and (4) are probably caused by the fact that the medium S has a hard-to-bend structure, and cannot appropriately disperse the bending stress.

### SUMMARY OF THE INVENTION

Accordingly, an object of the invention is to provide an image forming method and an image forming apparatus of forming an image on a reversible image display medium, and particularly to provide the image forming method and the image forming apparatus, which can reduce a cost of the reversible image display medium.

The above reversible image display medium has a pair of substrates, at least one of which has light-transparency, one or more developer accommodating cells, which are formed between the pair of substrates and are surrounded by a wall, and dry developer accommodated in each of the developer accommodating cells. The dry developer includes at least two kinds of developing particles having frictional charging properties and being different in charging polarity and optical reflectance density from each other.

At least one of these kinds of the dry particles may have magnetic properties. The above reversible image display medium may also be referred to as the “image display medium of the dry developing particle moving type” hereinafter.

Another object of the invention is to provide an image forming method and an image forming apparatus of forming an image on the image display medium of the dry developing particle moving type, and particularly to provide the image forming method and the image forming apparatus, which can reduce a possibility of an electric shock of a user due to touch of the medium during image formation.

Still another object of the invention is to provide an image forming method and an image forming apparatus of forming an image on the image display medium of the dry developing particle moving type, and particularly to provide the image forming method and the image forming apparatus, which can reduce or eliminate a possibility of breakage of the medium, and can provide good images in connection with contrast, image density and others.

The invention provides an image forming method and an image forming apparatus described below.

(1) Image Forming Method

An image forming method of forming an image on a reversible image display medium including a pair of substrates including at least one substrate having light-transparency, at least one developer accommodating cell formed between the paired substrates and surrounded by a wall, and dry developer contained in each of the cell(s), the dry developer including at least two kinds of developing particles having frictional charging properties and being different in charging polarity and optical reflectance density from each other, wherein
the reversible image display medium includes the paired substrates made of a nonconductive material, and the image is formed on the reversible image display medium by transporting the reversible image display medium while keeping the reversible image display medium in uniform surface-contact with an electrostatic field applying member for image formation by a conductive member supplied with a developing bias.
   (2) Image Forming Apparatus

An image forming apparatus of forming an image on a reversible image display medium including a pair of substrates including at least one substrate having light-transparency, at least one developer accommodating cell formed between the paired substrates and surrounded by a wall, and dry developer contained in each of the cell(s), the dry developer including at least two kinds of developing particles having frictional charging properties and being different in charging polarity and optical reflectance density from each other, wherein
the image forming apparatus includes an electrostatic field applying member for applying an electrostatic field for image formation to the reversible image display medium, and a conductive member keeping the medium in uniform surface-contact with the electrostatic field applying member while allowing transportation of the medium, and being supplied with a developing bias, and
the paired substrates are made of a nonconductive material.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1(A) is a schematic cross section showing an example of a part of an image display medium for image formation in an image non-displaying state, and FIG. 1(B) shows an example of the medium in an image displaying state.

FIG. 2 shows a schematic structure of an image forming apparatus according to an embodiment of the invention.

FIG. 3 shows a modification of the apparatus of the first embodiment.

FIG. 4 shows another modification of the apparatus of the first embodiment.

FIG. 5 shows a schematic structure of an image forming apparatus according to a second embodiment.

FIG. 6 shows a schematic structure of an image forming apparatus according to a third embodiment.

FIG. 7 shows a schematic structure of an image forming apparatus according to a fourth embodiment.

FIG. 8 shows a schematic structure of an image forming apparatus according to a fifth embodiment.

FIG. 9 shows an example of a method of forming an image on a medium having a conductive layer.

FIG. 10 shows another example of a method of forming an image on a medium having a conductive layer.

FIG. 11 shows an example of an image display medium having a conductive layer with a certain part cut away.

FIG. 12 shows an example of breakage of the medium due to execution of the image forming method shown in FIG. 10.

### DESCRIPTION OF THE PREFERRED EMBODIMENTS

An image forming method according to an embodiment of the invention is basically an image forming method of forming an image on a reversible image display medium including a pair of substrates including at least one substrate having light-transparency, one or more developer accommodating cell(s) formed between the paired substrates and surrounded by a wall, and dry developer contained in each of the cell(s), the dry developer including at least two kinds of developing particles having frictional charging properties and being different in charging polarity and optical reflectance density from each other.

The reversible image display medium includes the paired substrates made of a nonconductive material, and the image is formed on the reversible image display medium by transporting the reversible image display medium while keeping the reversible image display medium in uniform surface-contact with an electrostatic field applying member for image formation by a conductive member supplied with a developing bias.

An image forming apparatus according to an embodiment of the invention is basically an image forming apparatus of forming an image on a reversible image display medium including a pair of substrates including at least one substrate having light-transparency, one or more developer accommodating cell(s) formed between the paired substrates and surrounded by a wall, and dry developer contained in each of the cell(s), the dry developer including at least two kinds of developing particles having frictional charging properties and being different in charging polarity and optical reflectance density from each other.

The image forming apparatus includes an electrostatic field applying member for applying an electrostatic field for image formation to the reversible image display medium, and a conductive member keeping the medium in uniform surface-contact with the electrostatic field applying member while allowing transportation of the medium, and being supplied with a developing bias. The paired substrates are made of a nonconductive material.

According to the above image forming method and apparatus, the image display medium of the dry developing particle moving type, which is an image formation target, includes the paired substrates made of a nonconductive material, but the medium is kept in contact with the electrostatic field applying member for image formation by the conductive member supplied with the developing bias. Thereby, the at least two kinds of contained developing particles, which have frictional charging properties and are different in charging polarity and optical reflectance density (i.e., different in contrast or color) from each other, are moved oppositely relatively to each other by the Coulomb force caused by the electric field so that the image is formed. Further, nevertheless a conductive layer is not employed on the medium for image formation in contrast to the conventional structures, the image can be formed. Images can be erased and rewritten, e.g., by applying different electric fields.

Since the conductive layer on the medium is not required, this can reduce a manufacturing cost of the image display medium.

The pair of substrates are not conductive, and the conductive layer is not required. This can reduce the possibility of an electric shock of a user due to touch of the medium during image formation.

Since the conductive member keeps the medium in surface-contact with the electrostatic field applying member during transportation of the medium, the medium is in contact with the electrostatic field applying member for a long time, and therefore a developing time (developing bias applying time) can be long so that the electric field acting on the medium-contained developing particles spreads, and the developing particles are moved for a longer time. Owing to these factors, the formed image can have good contrast, image density and others, and can be stable for a long term. Even after the medium is repetitively used, the image can be formed with good image reproducibility.

Since the conductive member keeps the medium in uniform surface-contact with the electrostatic field applying member during the transportation of the medium, such situations are sufficiently suppressed that a locally large stress occurs to bend the medium irregularly and/or to peel off a wall defining the cell from the substrate. Accordingly, the image can be formed in a good state, which can suppress breakage of the medium.

In the image forming method and the image formation by the image forming apparatus, the image display medium of dry developing particle moving type, which is the image formation target, may include magnetic developing particles as at least one kind of the developing particles between the at least two kinds of developing particles having frictional charging properties and being different in charging polarity and optical reflectance density from each other. In this case, a magnetic field applying device may be employed, which applies a magnetic field for stirring the developer in the medium during transportation of the reversible image display medium kept in surface-contact with the electrostatic field applying member by the conductive member supplied with the developing bias.

By employing the above magnetic field applying device, the developer containing the magnetic developing particles can be stirred to improve movability for image formation so that good images can be formed more easily and reliably.

It is preferable that the magnetic force of the magnetic field applying device does not excessively stir the developer to disturb the image immediately before the end of image formation region, i.e., immediately before or after the end of an electrostatic field applying region. For example, the above magnetic force may exhibit a magnetic flux density of 100 Gs or less at a downstream end, in the medium transporting direction, of a region, where the medium is in surface-contact with the electrostatic field applying member, and more preferably, may have the magnetic flux density of 50 Gs or less.

The conductive member supplied with the developing bias may selected from the following members.

(1) A conductive belt, which is driven in the transporting direction of the medium while keeping the medium in uniform surface-contact with the electrostatic field applying member. Preferably, the conductive belt is an endless belt, which can be passed around a pair of rollers, and is arranged in contact with the electrostatic field applying member so that it can keep the image display medium in uniform surface-contact with the electrostatic field applying member.

(2) A conductive guide member having a surface portion, which is opposed to and extends along the electrostatic field applying member. This surface portion of the conductive guide member keeps the medium in uniform surface-contact with the electrostatic field applying member while allowing transportation of the medium.

(3) A group of rollers, which are arranged successively along the electrostatic field applying member. These rollers keep and hold the medium in uniform surface-contact with the electrostatic field applying member while transporting the medium. If necessary, a medium guide member may be arranged between the neighboring rollers in the roller group. Preferably, the roller group includes three or more conductive rollers.

In any one of the above structures, the whole of the conductive member supplied with the developing bias may be electrically conductive. However, only a part of the conductive member may be conductive provided that the member can apply the developing bias to the image display medium. For example, at least a surface portion, which keeps the image display medium in uniform surface-contact with the electrostatic field applying member, may have conductivity, and this portion may be supplied with the developing bias.

In the image forming method, the electrostatic field applying member may be typically a photosensitive member such as a photosensitive drum or a photosensitive belt, on which an electrostatic latent image corresponding to an image to be formed is formed. In the case of the image forming apparatus, the electrostatic field applying member may be a photosensitive member such as a photosensitive drum or a photosensitive belt, and a latent image forming device for forming an electrostatic latent image thereon may be employed.

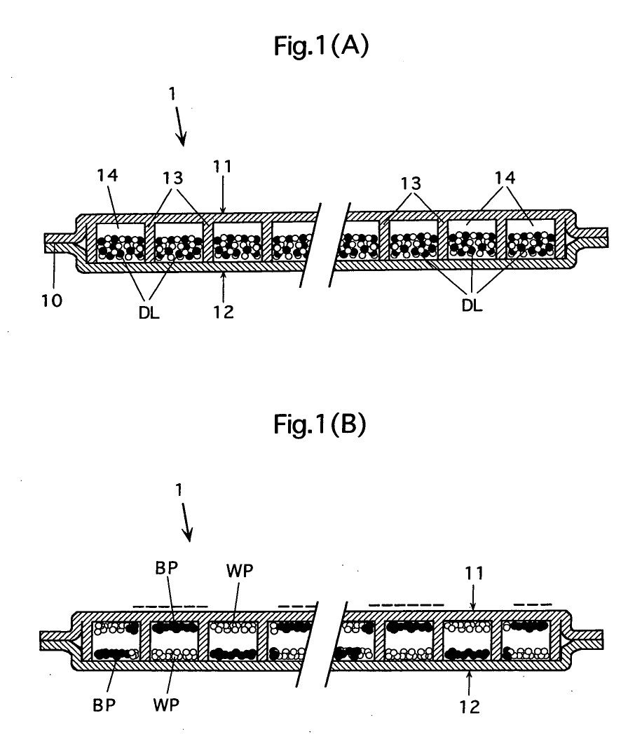

The image forming method and image forming apparatus will be described by way of example with reference to the drawings. Prior to such description, description will now be given on an example of a reversible image display medium of a dry developing particle moving type. FIGS. 1(A) and 1(B) show schematic cross sections of a part of an example of a medium. FIG. 1(A) shows a state before image display, and FIG. 1(B) shows an image-displayed state.

An image display medium 1 basically includes paired substrates opposed to each other, developer-accommodating cells formed between the substrates and dry developer accommodated in the cells. The dry developer includes at least two kinds of developing particles, which have frictional charging properties, and are different in charging polarity and optical reflectance density (i.e., different in contrast or color) from each other.

This will be described below with reference to the drawings. The medium 1 has a substrate 11 on an image viewing side and a substrate 12 on the opposite side. These substrates 11 and 12 are opposed to each other with a predetermined gap therebetween. Partitions 13 are arranged between the substrates 11 and 12 for ensuring the predetermined gap between the substrates. The partitions 13 serve also as a spacer between the substrates 11 and 12.

The partitions 13 are arranged in a plurality of positions, respectively, and extend in the direction of a short side of the substrate 11. A developer accommodating cell 14 is formed between the neighboring partitions 13.

The substrates 11 and 12 in this example may be flexible resin film substrates. At least the substrate 11 on the image viewing side has light-transparency so that a user can view the developing particles, which are arranged inside the medium for contributing to the image display, and more preferably is made of a transparent substrate. In this example, the partitions 13 are integral with the substrate 11.

Each cell 14 accommodates dry developer DL containing white and black developing particles WP and BP, which are frictionally charged and are different in charging polarity from each other. The white developing particles WP are negatively chargeable particles, and the black developing particles BP are positively chargeable magnetic particles. These are frictionally charged by friction between them.

After a predetermined amount of developer DL is accommodated in each cell 14, the substrate 12 is kept in contact with top surfaces of the partitions 13, and is adhered thereto by adhesive or the like. Heat sealing is effected on peripheral portions 10 of the substrates 11 and 12. In this manner, each cell 14 is surrounded by a wall including a partition 13 and sealed so that the developer DL does not leak from the cells 14.

The substrates 11 and 12 preferably have the following electric characteristics.

For preventing blurring of the electrostatic latent image written from a photosensitive drum or photosensitive belt, as will be described later, it is preferable that the substrate 11 on the image viewing side substantially has a surface resistivity of about 10¹⁰ ohm/square (ohm/□) or more. Since the tendency of blurring of the electrostatic latent image also depends on the thickness of the substrate 11, the above value is not restrictive.

It is preferable that the rear substrate 12, which is in contact with the conductive member supplied with the developing bias, has a surface resistivity of a lower value within a range higher than about 10⁵ ohm/square(ohm/□). The lower surface resistivity achieves more reliable electric connection between the conductive member and the medium 1, and thus achieves more accurate image formation. However, the surface resistivity of an excessive low value causes a possibility of an electric shock of the user due to touch of the image display medium in an image output operation.

### First Embodiment

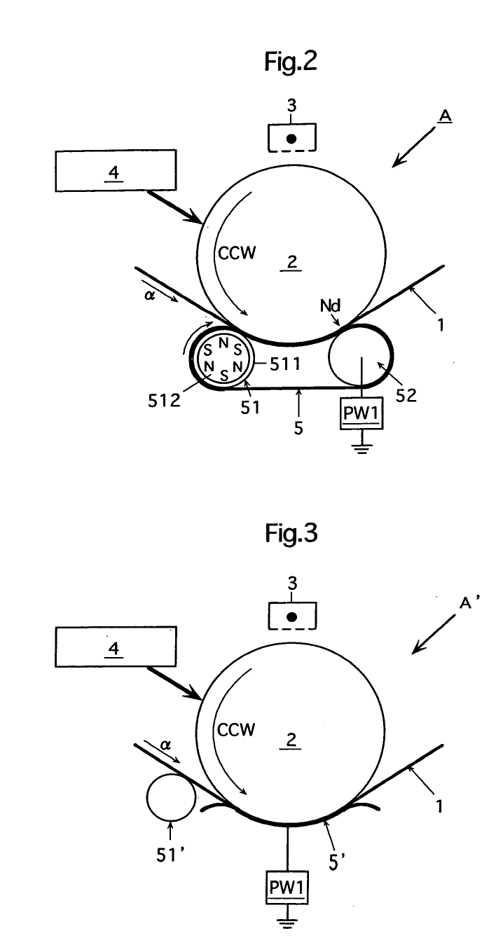

FIG. 2 shows an image forming apparatus according to a first embodiment. An image forming apparatus A has a photosensitive drum 2, which is driven to rotate in a counterclockwise direction CCW in the figure by drive means (not shown), and also includes a charger 3, an image exposing device (i.e., an example of electrostatic latent image forming device) 4 and a conductive endless belt 5 for applying a developing bias, which are arranged in this order around the photosensitive drum 2.

The conductive endless belt 5 is wound around a pair of rollers 51 and 52, and is arranged in contact with the photosensitive drum 2 so that it may uniformly keep the medium 1 in surface-contact with the surface of the photosensitive drum 2 in a pressed state.

The roller 51 is located upstream in a transporting direction of the medium 1 indicated by an arrow α in FIG. 2. The upstream roller 51 includes a sleeve 511 and a magnet roller 512 arranged in the sleeve 511. The sleeve 511 is driven to rotate by drive means (not shown) in the direction driving the belt 5 in the medium transporting direction. The magnet roller 512 is driven to rotate by drive means (not shown) independently of the sleeve 511.

The downstream roller 52 is a conductive roller, and is driven by the conductive belt 5. A power source PW1 supplies a developing bias to the conductive belt 5 via this roller 52.

The material and others of the conductive belt 5 is not restricted provided that it can apply the developing bias to the medium 1, but it is preferable that the conductive belt 5 has a surface resistivity of 10⁵ ohm/square or less and a volume resistivity of 10⁵ ohm·cm or less. However, the material can be appropriately selected according to an electric resistance of a rear surface of the medium, a length (nip length) in the medium transporting direction of the contact region between the photosensitive drum 2 and the medium 1, and the structure of the developing bias applying portion. For example, if the conductive belt 5 has the surface resistivity of about 10⁵ ohm/square, it is preferable to employ a structure, in which the developing bias is applied to the downstream roller 52 as shown in the figure.

The image forming apparatus A forms an image on the medium 1 as described below.

The charger 3 uniformly charges the surface of the photosensitive drum 2 to bear a predetermined potential, and the image exposing device 4 effects the image exposure corresponding to the image to be formed on a region thus charged so that an electrostatic latent image is formed. A medium supply portion (not shown) supplies the medium 1 to the position between the photosensitive drum 2 and the conductive belt 5 in synchronization with the electrostatic latent image on the photosensitive drum 2 while directing the substrate 11 on the image viewing side toward the photosensitive drum 2. Thereby, the belt 5 transports the medium 1 while uniformly keeping the medium 1 in intimate surface-contact with the photosensitive drum 2.

In this manner, the magnet roller 512 stirs the developer DL including black magnetic particles BP in the medium 1 to attain the state, in which each developing particle can move easily. At the same time, the electrostatic latent image on the photosensitive drum 2 is written (i.e., transferred or induced) onto the medium 1, and the conductive belt 5 applies the predetermined developing bias to the medium 1.

In this manner, the electrostatic field is applied to the developer DL in the medium 1 for forming the image, and the Coulomb force moves the white and black developing particles WP and BP in the opposite directions so that the image corresponding to the electrostatic latent image is formed.

According to the image formation of this embodiment, the image is formed although the medium 1 does not include a conventional conductive layer. Since the conductive layer is not required, the image display medium 1 can have a simple structure, and can be manufactured at a low cost.

Since the pair of substrates are substantially nonconductive, and do not require the conductive layer, it is possible to reduce the possibility of an electric shock of the user due to touch of the medium during the image formation.

Since the conductive belt 5 uniformly keeps the medium 1 in intimate surface-contact with the surface of the photosensitive drum 2 while the medium 1 is being transported, this can suppress blurring of the electrostatic latent image, which is written (i.e., transferred or induced) from the photosensitive drum 2 onto the medium 1, and can increase the time, for which the medium 1 is in contact with the electrostatic latent image on the photosensitive drum 2. Thereby, the developing time (developing bias applying time) can be long. This long developing time increases the range of the electric field acting on the developing particles contained in the medium, and can increase the time, for which the developing particles are moved. Thereby, the images having good resolutions, contrast, image densities and others can be stably maintained for a long term. Even after repeating of use, the images can be formed with good image reproducibility.

Since the conductive belt 5 uniformly keeps the medium 1 in intimate surface-contact with the photosensitive drum 2 while the medium 1 is being transported, such situations can be sufficiently suppressed that a large local stress occurs to bend the medium 1 and/or the partitions 13 forming the cells are peeled off from the substrate 12. Therefore, the good images can be formed safely while suppressing breakage of the medium 1.

The above can be probably achieved owing to the fact that the medium 1 pressed onto the belt 5 bends uniformly, and the tension of the belt 5 uniformly pushes the medium 1 onto the photosensitive drum 2 to disperse the stress so that the local stress can be prevented.

Since the image forming apparatus A is configured to keep uniformly the medium 1 in intimate surface-contact with the photosensitive drum 2 by the belt, the structure of the apparatus can be simple, and can be inexpensive.

As a modification of the first embodiment, the invention may provide an image forming apparatus A′ shown in FIG. 3. In the image forming apparatus A′, the conductive belt 5 in the apparatus A in FIG. 2 is replaced with a conductive guide member 5′, which is opposed to the photosensitive drum 2, is curved along the surface of the photosensitive drum and is supplied with the developing bias. The medium 1 is moved through a position between the guide member 5′ and the photosensitive drum 2 so that the medium 1 is uniformly kept in surface-contact with the photosensitive drum 2. In this case, a roller 51′ is arranged upstream to the guide member 5′. The roller 51′ is a magnet roller, or is formed of a sleeve, which is driven to rotate, and a magnet roller arranged therein.

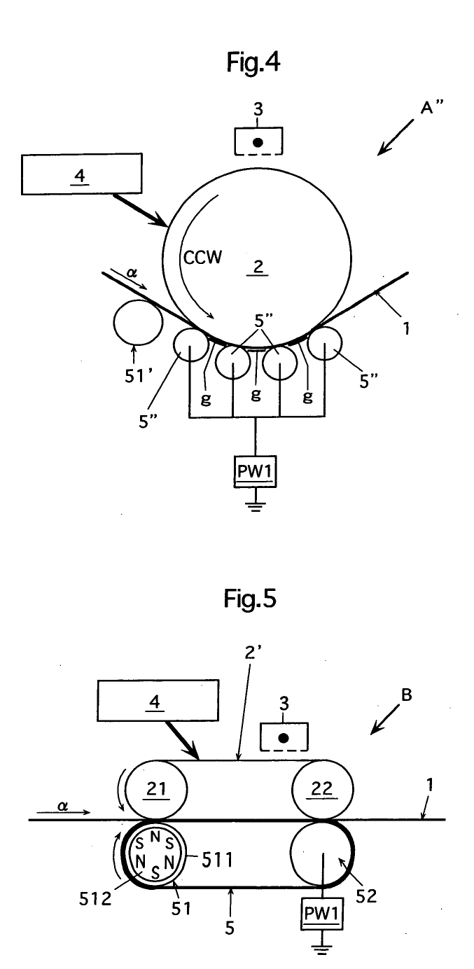

An image forming apparatus A″ shown in FIG. 4 may also be employed. In the image forming apparatus A″, the conductive belt 5 in the apparatus A shown in FIG. 2 is replaced with a roller group including three or more conductive rollers 5″, which are opposed to the photosensitive drum 2, are arranged along the surface of the photosensitive drum 2 and are supplied with the developing bias. The medium 1 is moved through a position between the group of rollers 5″ and the photosensitive drum 2 so that the medium 1 is uniformly kept in surface-contact with the photosensitive drum 2. In FIG. 4, “g” indicates guide members arranged between the rollers 5″. In this structure, the roller 51′ is arranged upstream to the group of rollers 5″. The roller 51′ is a magnet roller, or is formed of a sleeve, which is driven to rotate, and a magnet roller arranged therein.

In any of the above structures, it is preferable that the magnetic field applying device such as the magnet roller exhibits the magnetic flux density of 100 Gs or less at a downstream end Nd, in the medium transporting direction, of a region, where the medium 1 is in pressure-contact with the photosensitive member, and more preferably, may exhibit the magnetic flux density of 50 Gs or less. This is true also in the following embodiments. Instead of the magnet roller, the magnetic field applying device may be formed of a magnet sheet or the like having N- and S-type polarities in alternate positions.

### Second Embodiment

FIG. 5 shows an image forming apparatus according to a second embodiment. An image forming apparatus B differs from the image forming apparatus A shown in FIG. 2 in that a photosensitive belt 2′ is employed instead of the photosensitive drum 2, and is passed around a pair of pulleys 21 and 22. A portion of the conductive belt 5, which uniformly keeps the medium 1 in surface-contact with the photosensitive belt 2′ is arranged parallel to the photosensitive belt 2′. Structures other than the above are the same as those of the apparatus A, and the same parts and portions as those of the apparatus A bear the same reference symbols.

The image forming apparatus B can achieve effects similar to those of the apparatus A. In particular, since the apparatus B employs the photosensitive belt as the photosensitive member, the medium 1 is not bent so that the bending stress can be reduced in the medium 1. At the same time, it is possible to prevent deformation of the cells in the medium 1 in the image output operation. This also improves the image quality.

### Third Embodiment

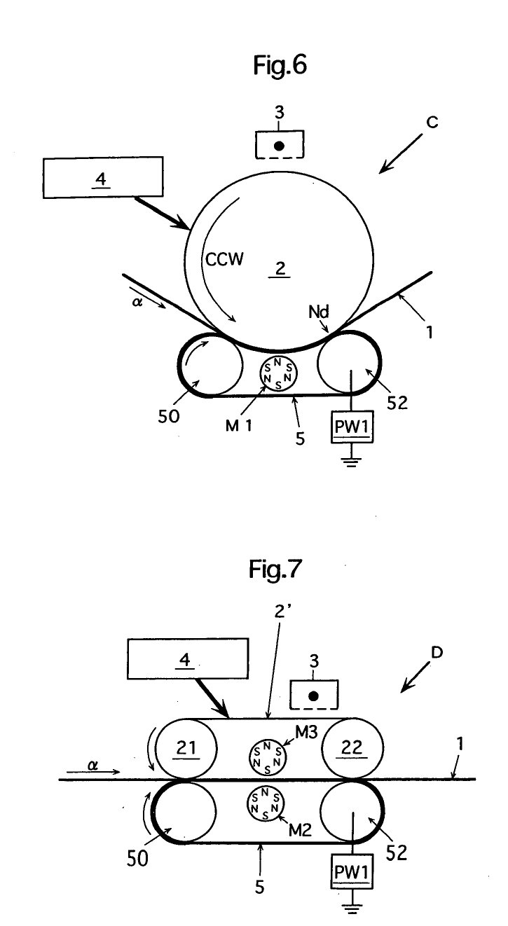

FIG. 6 shows an image forming apparatus according to a third embodiment. This image forming apparatus C differs from the image forming apparatus A shown in FIG. 2 in that the upstream roller 51 for carrying the conductive belt 5 in FIG. 2 is replaced with a mere belt-driving roller 50 not including a magnet roller, and a magnet roller M1, which is driven to rotate, is arranged between the roller 50 and the conductive roller 52, which applies the developing bias, and is opposed to the medium 1 passing between the belt 5 and the photosensitive drum 2. Structures other than the above are the same as those of the apparatus A, and the same parts and portions as those of the apparatus A bear the same reference symbols.

According to this apparatus C, the magnet roller M1 stirs the developer in the medium 1 so that the image is formed in the medium 1 similarly to the apparatus A.

This apparatus C has such a feature that the magnet roller M1 is not used for transporting the medium 1, and therefore is not required to be arranged inside a sleeve so that the structure thereof can be simple.

Further, the respective members can substantially achieve functions in a separated manner, respectively. For example, the magnet roller M1 solely achieves its function. The roller 52 can solely achieve the function of applying the developing bias while pressing the belt 5 onto the photosensitive drum 2 via the medium 1. The roller 50 can solely achieve the function of rotating the belt while pressing the medium 1 onto the photosensitive drum 2 (and the function of correcting meandering of the belt).

Since the magnet roller M1 is not covered with a sleeve, and can be arranged near the medium 1, the developer stirring force similar to that of the magnet roller 512 in the apparatus shown in FIG. 2 can be achieved even with the magnet force smaller than that of the magnet roller 512, and therefore the cost and sizes of the image forming apparatus can be reduced.

By separating the functions as described above, one or more additional magnet roller(s) can be easily arranged for increasing the developer stirring time and/or developer stirring force.

For preventing unbalanced dispersion of the developer, the apparatus may employ two or more magnet rollers, which rotate, e.g., in different directions.

### Fourth Embodiment

FIG. 7 shows an image forming apparatus of a fourth embodiment. This image forming apparatus D is of the function-separated type similar to that of the apparatus C of the third embodiment.

The apparatus D employs the mere belt-driving roller 50 not including the magnet roller instead of the roller 51, which contains the magnet roller and carries the conductive belt 5 in the apparatus B shown in FIG. 5, and also employs a magnet roller M2 arranged inside the belt 5 and a magnet roller M3 arranged inside the photosensitive belt 2′. These rollers M2 and M3 are opposed to the medium 1 with the belts therebetween. Structures other than the above are similar to those of the apparatus B. This apparatus D can stir the developer from the image viewing side in addition to the rear side.

### Fifth Embodiment

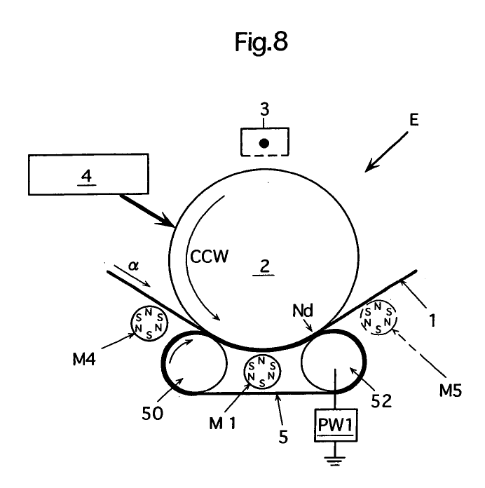

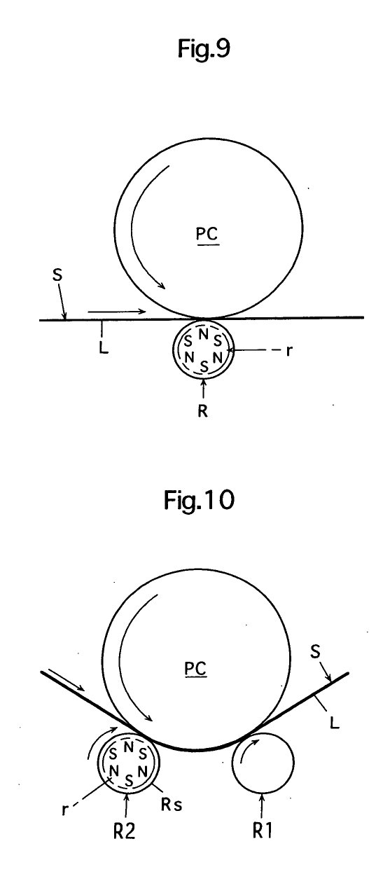

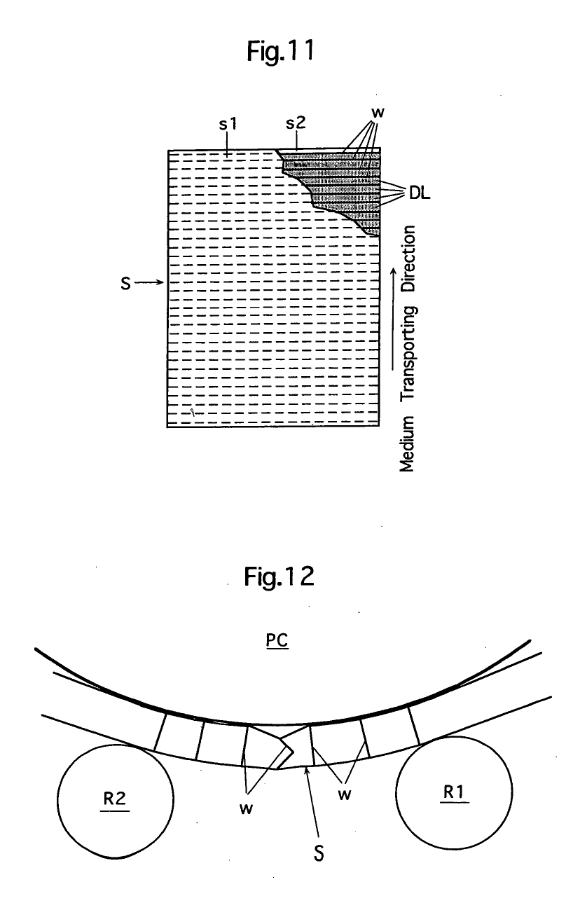

FIG. 8 shows an image forming apparatus of a fifth embodiment. An image forming apparatus E differs from the apparatus C of the third embodiment in that one magnet roller M4 is additionally arranged outside a nip portion between the photosensitive drum 2 and the conductive belt 5. Structures other than the above are the same as those of the apparatus C.

This apparatus E can sufficiently stir the developer in the medium before applying the electrostatic field. Therefore, the developing particles move rapidly even in an initial state of application of the electrostatic field, and it is possible to develop correctly the particles, which are in contact with the substrate 11 on the image viewing side close to the viewer, so that the image of high quality can be formed. Such a structure may be employed that a sleeve (not shown) is fitted around the magnet roller M4, a bias-applying roller is opposed to this sleeve with the medium 1 therebetween, and a voltage for display in light grey is applied to the bias-applying roller. Thereby, such a situation can be prevented that all the white particles are simultaneously developed. Therefore, the image quality can be further increased.

A magnetic field applying device such as a magnet roller M5 may be arranged outside and downstream from the nip portion. This provision of the magnet roller M5 can uniformly redistributes the irregularly distributed developer. For preventing breakage of the image, it is preferable that the magnetic field applying device such as the magnet roller M5 exhibits the magnetic flux density of 100 Gs or less, and more preferably 50 Gs or less.

Although the present invention has been described and illustrated in detail, it is clearly understood that the same is by way of illustration and example only and is not to be taken by way of limitation, the spirit and scope of the present invention being limited only by the terms of the appended claims.

1. An image forming method of forming an image on a reversible image display medium including a pair of substrates including at least one substrate having light-transparency, at least one developer accommodating cell formed between said paired substrates and surrounded by a wall, and dry developer contained in each said cell, the dry developer including at least two kinds of developing particles having frictional charging properties and being different in charging polarity and optical reflectance density from each other, wherein
said reversible image display medium includes said paired substrates made of a nonconductive material, and the image is formed on said reversible image display medium by transporting said reversible image display medium while keeping said reversible image display medium in uniform surface-contact with an electrostatic field applying member for image formation by a conductive member supplied with a developing bias.

2. The image forming method according to claim 1, wherein
said reversible image display medium includes magnetic developing particles as at least one kind of the developing particles in said at least two kinds of developing particles having frictional charging properties and being different in charging polarity and optical reflectance density from each other, and a magnetic field applying device applies a magnetic field for stirring the developer in said medium during transportation of said reversible image display medium kept in surface-contact with said electrostatic field applying member by the conductive member supplied with said developing bias.

3. The image forming method according to claim 2, wherein
a magnetic force of said magnetic field applying device exhibits a magnetic flux density of 100 Gs or less at a downstream end, in the medium transporting direction, of a region of the surface-contact between said medium and said electrostatic field applying member.

4. The image forming method according to claim 1, wherein
said method employs, as said conductive member supplied with said developing bias, a conductive belt driven in the transporting direction of said medium while keeping said medium in uniform surface-contact with said electrostatic field applying member.

5. The image forming method according to claim 1, wherein
said method employs, as said conductive member supplied with said developing bias, a conductive guide member having a surface portion opposed to and extending along said electrostatic field applying member, and said surface portion keeps said medium in uniform surface-contact with said electrostatic field applying member while allowing transportation of the medium.

6. The image forming method according to claim 1, wherein
said method employs, as said conductive member supplied with said developing bias, a group of rollers arranged successively along said electrostatic field applying member, and said rollers keep and hold said medium in uniform surface-contact with said electrostatic field applying member while transporting the medium.

7. The image forming method according to claim 1, wherein
said electrostatic field applying member is a photosensitive member for carrying an electrostatic latent image corresponding to an image to be formed.

8. An image forming apparatus of forming an image on a reversible image display medium including a pair of substrates including at least one substrate having light-transparency, transparency, at least one developer accommodating cell formed between said paired substrates and surrounded by a wall, and dry developer contained in each said cell, said dry developer including at least two kinds of developing particles having frictional charging properties and being different in charging polarity and optical reflectance density from each other, wherein
said image forming apparatus comprises an electrostatic field applying member for applying an electrostatic field for image formation to said reversible image display medium, and a conductive member keeping said medium in uniform surface-contact with said electrostatic field applying member while allowing transportation of said medium, and being supplied with a developing bias, and
said paired substrates are made of a nonconductive material.

9. The image forming apparatus according to claim 8, wherein
said reversible image display medium includes magnetic developing particles as at least one kind of the developing particles in said at least two kinds of developing particles having frictional charging properties and being different in charging polarity and optical reflectance density from each other, and said image forming apparatus further comprises a magnetic field applying device for applying a magnetic field for stirring the developer in said medium during transportation of said reversible image display medium kept in surface-contact with said electrostatic field applying member by the conductive member supplied with said developing bias.

10. The image forming apparatus according to claim 9, wherein
said magnetic field applying device generates a magnetic force exhibiting a magnetic flux density of 100 Gs or less at a downstream end, in the medium transporting direction, of a region of the surface-contact between said medium and said electrostatic field applying member.

11. The image forming apparatus according to claim 8, wherein
said conductive member supplied with the developing bias is a conductive belt driven in the transporting direction of said medium while keeping said medium in uniform surface-contact with said electrostatic field applying member.

12. The image forming apparatus according to claim 8, wherein
said conductive member supplied with the developing bias is a conductive guide member having a surface portion opposed to and extending along said electrostatic field applying member, and said surface portion keeps said medium in uniform surface-contact with said electrostatic field applying member while allowing transportation of the medium.

13. The image forming apparatus according to claim 8, wherein
said conductive member supplied with the developing bias is a group of rollers arranged successively along said electrostatic field applying member, and said rollers keep and hold said medium in uniform surface-contact with said electrostatic field applying member while transporting the medium.

14. The image forming apparatus according to claim 8, wherein
said electrostatic field applying member is a photosensitive member, said image forming apparatus further comprises a latent image forming device for forming an electrostatic latent image corresponding to an image to be formed on said photosensitive member.
